(19) United States
(12) Patent Application Publication
(10) Pub. No.: US 2025/0365892 A1
(43) Pub. Date: Nov. 27, 2025

(54) IMMERSION TANK

(71) Applicant: PARADOX INFRASTRUCTURE, LLC, Vienna, OH (US)

(72) Inventor: KELLY BALLEW, BUCKHOLTS, TX (US)

(21) Appl. No.: 19/215,656

(22) Filed: May 22, 2025

Related U.S. Application Data
(60) Provisional application No. 63/650,545, filed on May 22, 2024.

(51) Int. Cl. H05K 7/20

(52) U.S. Cl. CPC H05K 7/20272; H05K 7/20236

(57) ABSTRACT

An immersion tank with a manifold coupled to an inlet and a weir coupled to an outlet. The manifold distributes a fluid throughout the immersion tank and promotes a laminar flow over immersed objects to the weir. The weir introduces a controlled turbulence to enhance cooling of returned fluid.

### CROSS REFERENCE TO RELATED APPLICATIONS

This application claims priority to and benefit of U.S. Provisional Patent Application Ser. No. 63/650,545 filed on May 22, 2024. The entirety of the aforementioned application is incorporated herein by reference.

### TECHNICAL FIELD

This application relates generally to an immersion tank and, more particularly, to an improved immersion tank with improved thermal characteristics.

### BACKGROUND

An immersion tank may be utilized to provide thermal cooling for an appliance or device. For instance, thermal management for computing systems may be achieved with an immersion tank. Computing components are submerged in a fluid held in the immersion tank. The fluid may be circulated as the fluid absorbs heat from the components. Immersion cooling is growing in popularity as thermal output of computing technology approaches the limits of air cooling.

### BRIEF SUMMARY OF THE INVENTION

A simplified summary is provided herein to help enable a basic or general understanding of various aspects of exemplary, non-limiting embodiments that follow in the more detailed description and the accompanying drawings. This summary is not intended, however, as an extensive or exhaustive overview. Instead, the sole purpose of the summary is to present some concepts related to some exemplary non-limiting embodiments in a simplified form as a prelude to the more detailed description of the various embodiments that follow.

In an aspect, an immersion tank includes an inlet to receive a fluid; a manifold coupled to the inlet, the manifold having a plurality of chambers, wherein each chamber includes a plurality of holes for emitting the fluid into an interior of the tank; a weir, wherein the weir includes a weir opening to receive a fluid from the interior of the tank into a weir cavity, the weir cavity includes a vortex generator coupled to an outlet of the weir cavity; and an outlet coupled to the outlet of the weir cavity.

These and other embodiments are described in more detail below.

### BRIEF DESCRIPTION OF THE DRAWING

Various non-limiting embodiments are further described with reference the accompanying drawings in which:

FIG. 1 is a perspective view of an exemplary, non-limiting embodiment of an immersion tank according to one or more aspects;

FIG. 2 is a top view of the exemplary, non-limiting embodiment of the immersion tank;

FIG. 3 is a cross-sectional view of the immersion tank along line 3 of FIG. 2;

FIG. 4 is a side view of the immersion tank;

FIG. 5 is a top cross-sectional view of the immersion tank along line 5 of FIG. 4;

FIG. 6 is a cross-sectional view of the immersion tank along line 6 of FIG. 4;

FIG. 7 is a cross-sectional view of the immersion tank along line 7 of FIG. 4;

FIG. 8 is top perspective view of an exemplary, non-limiting embodiment of a manifold of the immersion tank according to various aspects;

FIG. 9 is top perspective view of an exemplary, non-limiting embodiment of the manifold of the immersion tank according to various aspects;

FIG. 10 is a cross-sectional view of the manifold of the immersion tank; and

FIG. 11 is a partial, cross-sectional view of the manifold of the immersion tank . . .

### DETAILED DESCRIPTION OF THE INVENTION

As discussed in the background, an immersion tank may be utilized for cooling of devices and/or appliances. As thermal output for devices increases, the performance or capacity demands of the immersion cooling system also increases. An improved immersion tank for immersion cooling is described herein. The immersion tank includes a manifold and weir configuration to enhance delta-T performance. In addition, the immersion tank described herein controls fluid flow to promote uniformity of the temperature distribution in the tank.

The above noted features and embodiments will be described with reference to the drawings, wherein like reference numerals are used to refer to like elements throughout.

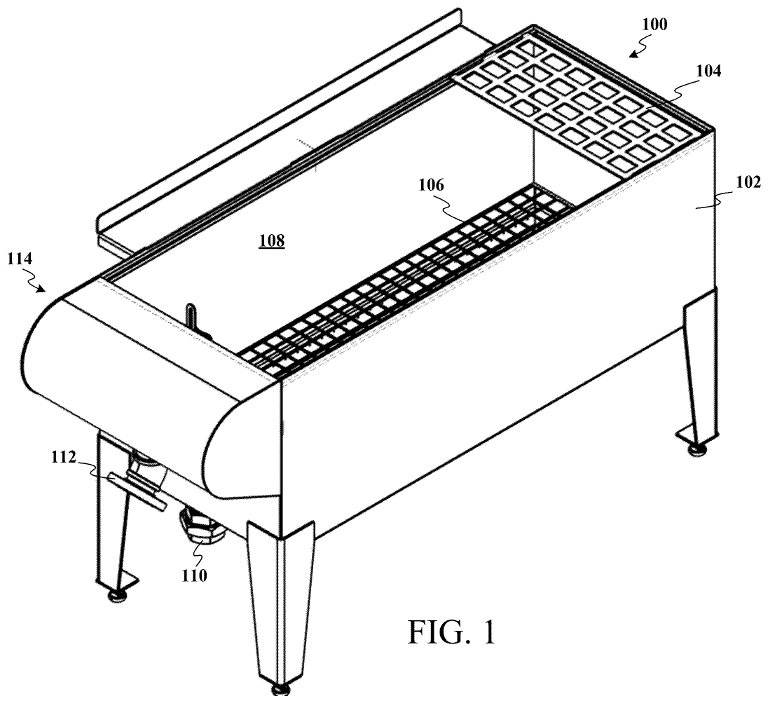

FIG. 1 shows a perspective view of an exemplary, non-limiting immersion tank 100. Tank 100 includes a housing 102, which may include several sidewalls to define an interior space 108. A mesh 106 may be inserted into interior space 108 to provide a surface on which components to be cooled may be supported. Immersion tank 100 may also include a drip tray 104 as shown in FIG. 1.

In one exemplary implementation, a fluid may be introduced into tank 100 to cool components placed therein. In the case of computing components, the fluid may be a dielectric fluid. Further, the fluid may be circulated through tank 100. For instance, fluid may be input to tank 100 via inlet 110 and exit the tank via outlet 112. As shown in FIG. 1, outlet 112 may be associated with a weir 114. Accordingly, fluid leaves the tank via weir 114 and outlet 112 after absorbing heat from objects placed in interior space 108.

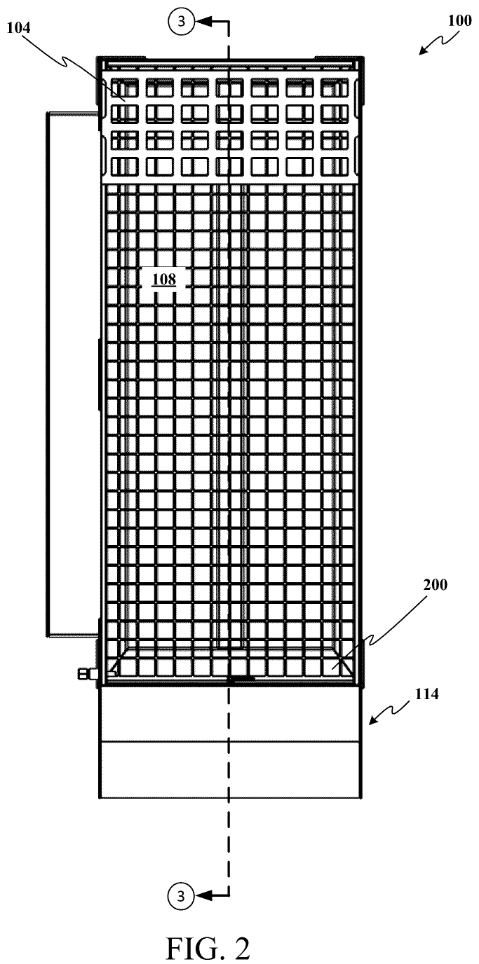

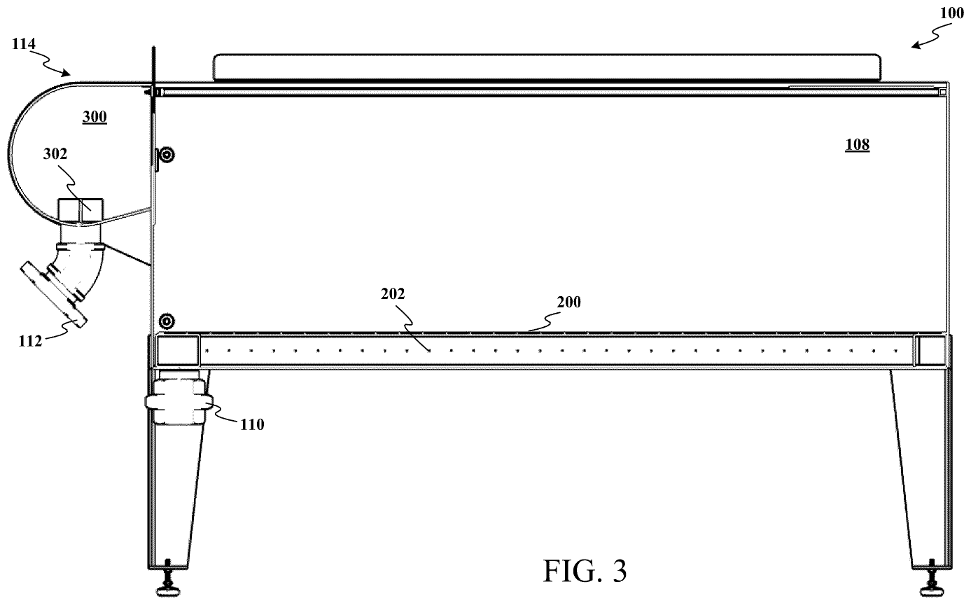

Turning briefly to FIG. 2, which is a top view of tank 100, a manifold 200 is located beneath mesh 106 within interior space 108. Manifold 200 is described in more detailed below. FIG. 3 is a cross-sectional view of tank 100 along line 3 indicated in FIG. 2. As shown in FIG. 3, manifold 200 includes a plurality of holes 202. Fluid may be introduced via inlet 110 into manifold 200. Manifold 200 distributes the fluid throughout tank 100 via the plurality of holes 202.

FIG. 3 also depicts a cross-section of weir 114. As shown in FIG. 3, weir 114 may be a circular weir and define a round weir cavity 300. In an aspect, fluid from tank 100 (e.g. from interior space 108) may enter the weir cavity 300 at a top portion and waterfall down to outlet 112. In a further aspect, a vortex generator 302 may be associated with outlet 112. The vortex generator 302 creates a swirling motion as the fluid flows over it. The swirling motion provides controlled turbulences to efficiently mix fluid layers and increase a surface area for heat exchange of exiting fluid.

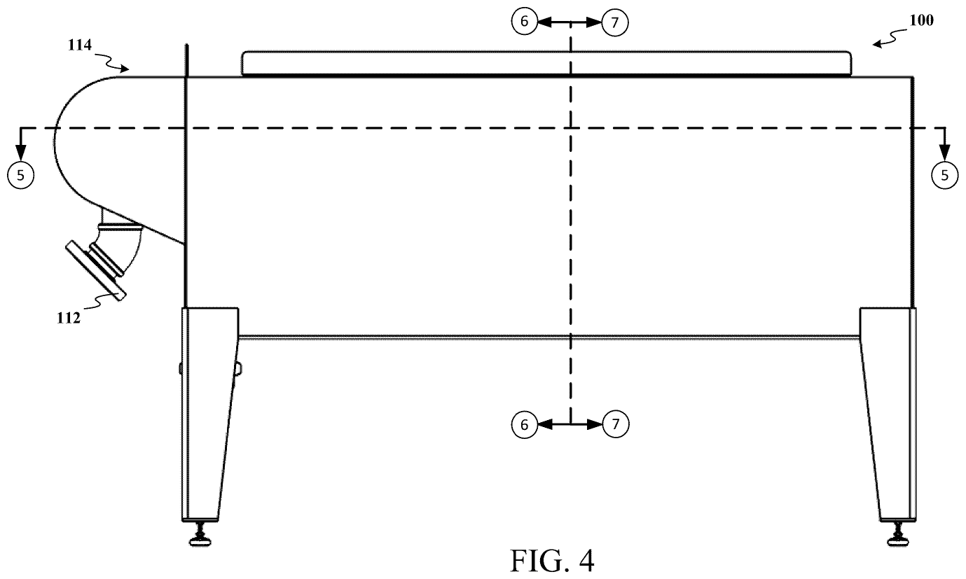

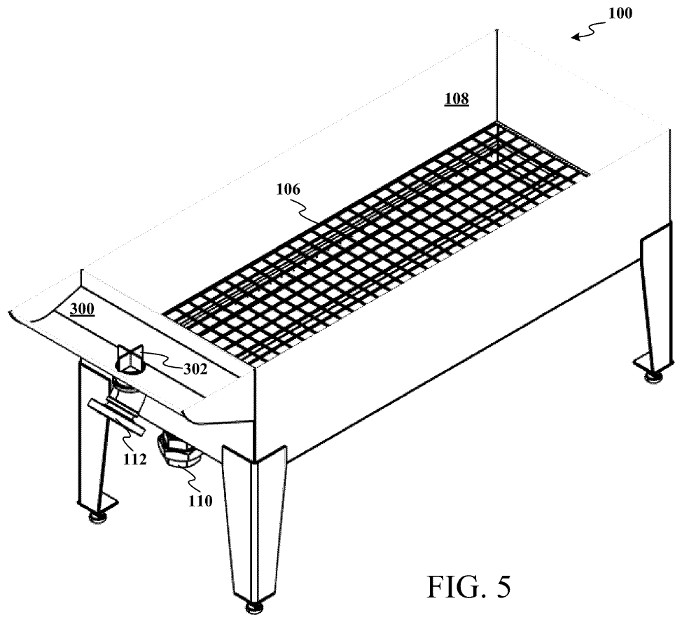

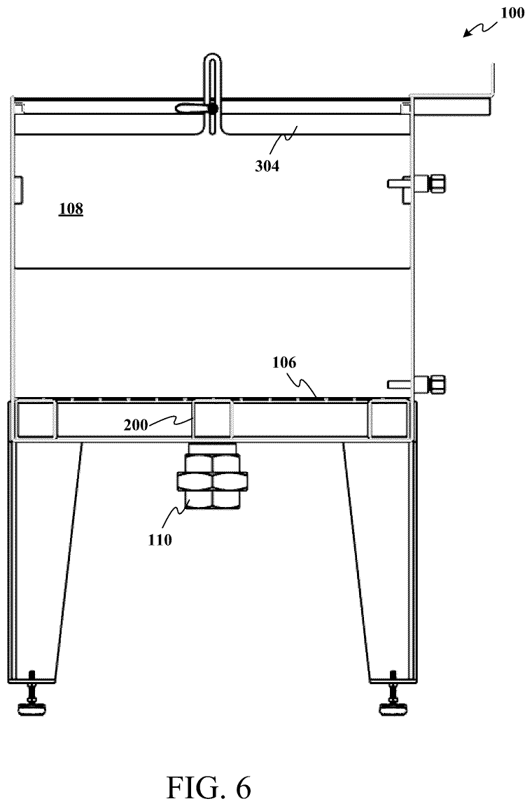

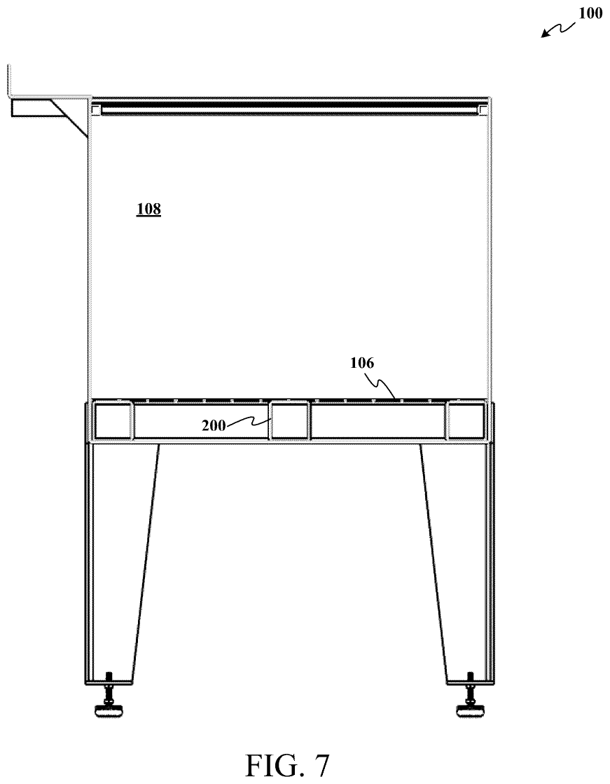

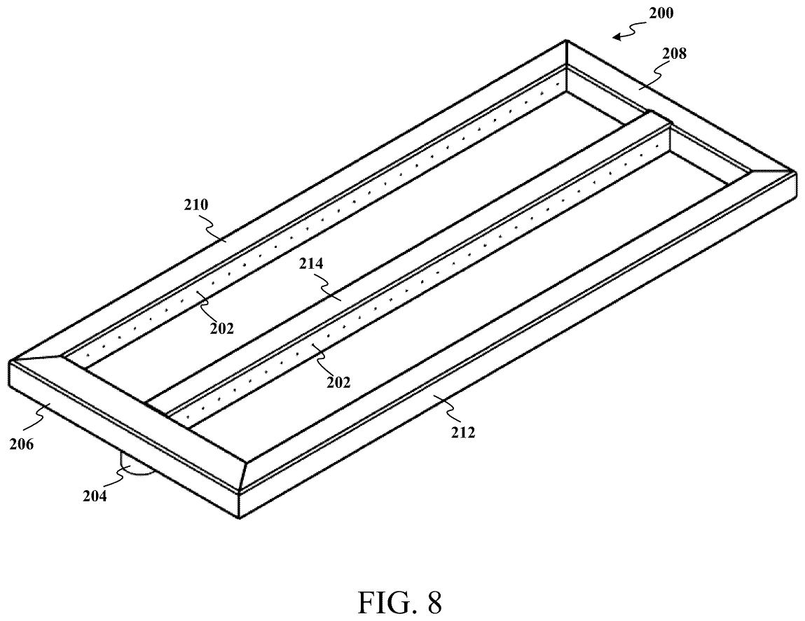

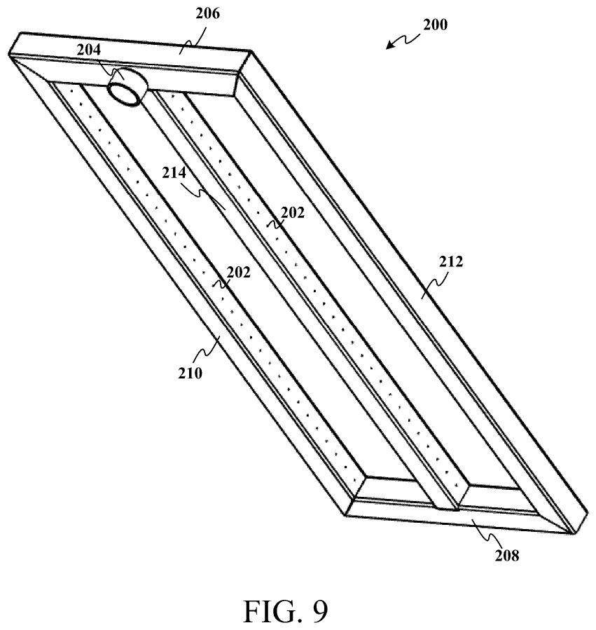

FIG. 4 is a side (non-sectional) view of tank 100 from the same perspective as FIG. 3. FIG. 5 is a top perspective sectional of tank 100 along line 5 shown in FIG. 4. FIG. 5 depicts outlet 112 and vortex generator 302 relative to the weir cavity 300. FIG. 6 is a cross-section of tank 100 along line 6 shown in FIG. 4. As best shown in FIG. 6, an opening 304 is provided at a front, top portion of tank 100. Fluid from interior space 108 (introduced via inlet 110 and manifold 200) may exit through opening 304 into weir 114. FIG. 7 is a cross-section of tank 100 along line 7 shown in FIG. 4. Accordingly, FIG. 6 illustrates a front half of tank 100 and FIG. 7 illustrates the other half of tank 100. As shown in FIGS. 6 and 7, and best shown in FIGS. 8-11, manifold 200 may be positioned at a bottom of tank 100 (e.g. a bottom of interior space 108) and extend along a complete perimeter and central longitude of interior space 108.

Now referring to FIGS. 8-10, manifold 200 is depicted. As shown, manifold 200 includes a first transverse conduit 206 and a second transverse conduit 208. The second transverse conduit 208 is longitudinally spaced from first transverse conduit 206 via a plurality of longitudinal conduits. The longitudinal conduits include a first longitudinal conduit 210, a second longitudinal conduit 212, and a central longitudinal conduit 214. The first transverse conduit 206, first longitudinal conduit 210, second transverse 208, and second longitudinal conduit 212 connect to define a shape substantially conforming to a perimeter of interior space 108 along a bottom portion. Central longitudinal conduit 214 extends between the first transverse conduit 206 and the second transverse conduit 208 along a line that bisects both transverse conduits. An inlet 204 of manifold 200 may couple to inlet 110 of tank 100. Inlet 204 may be provided on first transverse conduit 206 as shown in the figures.

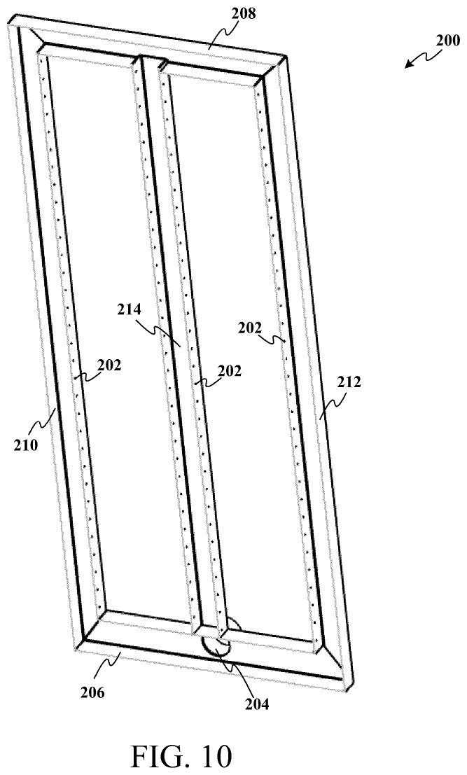

FIG. 10 shows a sectional view of manifold 200. In an aspect, central longitudinal conduit 214 is closed at an end that abuts first transverse conduit 206. Thus, fluid entering via inlet 204 flows from first transverse conduit 206, along first and second longitudinal conduits 210, 212, into second transverse conduit 208, and from the second transverse conduit 208 into the central longitudinal conduit 214. While fluid flows through the longitudinal conduits 210, 212, 214, fluid exits manifold 200 via the plurality of holes 202 positioned along the longitudinal conduits.

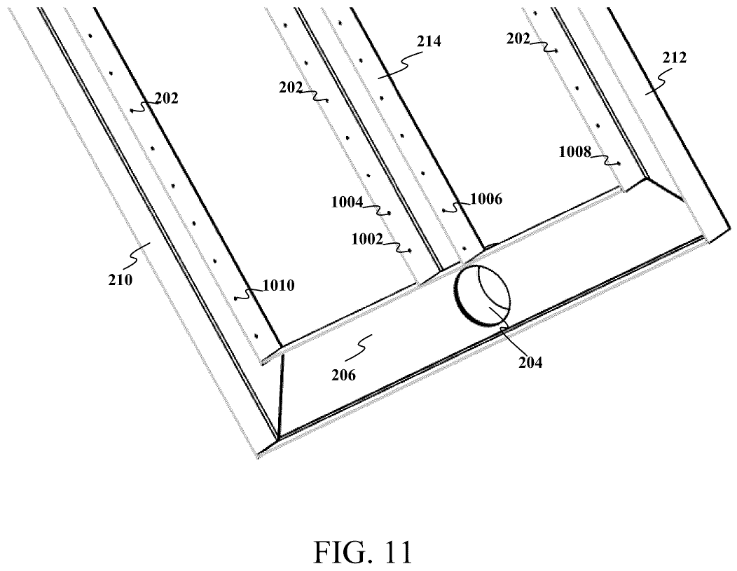

Turning to FIG. 11, a partial, cross-sectional view of the manifold 200 is shown to depict a configuration of the plurality of holes according to an aspect. As shown in FIG. 11, holes along one conduit are offset relative to holes on an adjacent conduit. In the case of central longitudinal conduit 214, the holes on one side are conduit 214 may be offset relative to the holes on the other side of conduit 214. Specifically, hole 1006 may be offset from hole 1008 in a longitudinal direction (e.g. longitudinal direction of manifold 200). Further, hole 1006 is offset from hole 1002 and hole 1004, which are located on an opposite side of conduit 214. Further, as shown in FIG. 11, hole 1010 may be offset from holes 1002 and 1004. In one exemplary implementation, adjacent holes may be separated by a first distance. That is, hole 1002 and hole 1004 are separated by the first distance. This separation distance may be maintained along a length of a side of a conduit. The offset may also be constant between respective lengths of sides of conduits.

In one example, the offset may be a fraction of the first distance. For instance, in some implementations, the first distance is one inch and the offset is 0.25 inches. In another example, the first distance may be two inches and the offset is 1 inch. EXEMPLARY IMPLEMENTATION OF IMMERSION TANK

The following description sets forth a detailed and specific exemplary implementation of an immersion tank according to one design. The features and details are exemplary of one possible implementation and other variations on the general structure described above are contemplated.

The manifold in the immersion tank may be engineered with three chambers, each measuring 3-by-3 inches square. This size accommodates a considerable volume of fluid while remaining compact enough to maintain precise control over fluid dynamics. Each chamber is drilled with ¼-inch holes spaced one inch apart. The holes are drilled to create an offset placement of these holes relative to those on adjacent sides. This offset is designed to reduce turbulence. Excessive turbulence can lead to inefficient fluid motion and energy loss.

The manifold includes three chambers that combine for a universal flow system. Each chamber has dimensions of 3-by-3 inches square. This dimension provides adequate volume to accommodate up to 300 gallons per minute without compromising the integrity of flow dynamics within the tank. Each chamber is equipped with ¼ inch holes spaced one inch apart. These holes are offset by ¼ inch relative to the adjacent chamber holes. In another example, each chamber is equipped holes spaced 2 inches apart. Further, in yet another example, the offset may be 1 inch relative to adjacent chamber holes. This offset is calculated to disrupt potential flow alignments that could lead to turbulent vortices. By disrupting turbulent vortices, a smooth and even flow along the manifold is maintained.

The offset perforation pattern is designed to produce maximum laminar flow within the tank. Laminar flow refers to a flow regime characterized by high momentum diffusion and low momentum convection. This flow type is useful for achieving uniform cooling effects as it prevents the formation of hot spots and ensures consistent fluid contact with the immersed items.

The offset holes provide numerous advantages. For example, by offsetting the holes, the manifold minimizes the colliding streams of fluid that typically create turbulence. This smoother flow facilitates maintaining a consistent fluid velocity and pressure across the entire surface area of the tank.

The offset arrangement promotes a laminar flow, where the fluid moves in parallel layers with minimal disruption between them. Laminar flow is advantageous in applications requiring uniform treatment across a surface, such as in cooling processes, because it enhances heat transfer efficiency and reduces the risk of hot spots.

The even laminar flow ensures that the cooling effect is uniformly distributed across the entire tank. This is particularly beneficial in applications like chemical reactions or component cooling where consistent temperature regulation is critical.

As described above, the immersion tank includes an innovative weir design. Traditional waterfall immersion tanks typically utilize a linear or a simplistic curved weir where water or the cooling medium flows over the edge in a waterfall-like fashion back into the tank. The primary mechanism for cooling in such systems is the direct contact between the fluid and the air as it cascades over the weir, which enhances heat dissipation through evaporation and convection as the fluid falls.

There are several limitations to conventional weir designs. The falling fluid inherently creates a turbulent flow as it splashes into the tank below. This turbulence can disturb the fluid dynamics and potentially affect the uniformity of the temperature distribution in the tank. Further, since the cooling mainly occurs at the surface where the fluid is exposed to air, the effectiveness of heat transfer may be limited to the upper layers of fluid and not engage the entire volume efficiently. In addition, maintaining a continuous waterfall flow often requires more energy for pumping and can lead to greater evaporation losses, necessitating additional fluid refills and temperature management.

The immersion tank described herein includes a circular weir design that improves on the traditional model by incorporating a form of turbulence, known as “controlled turbulence,” which is different from the chaotic turbulence seen in traditional waterfall systems. Unlike the disruptive turbulence in traditional waterfall designs, the circular 12 inch weir also includes a 3 inch internal Vortex that creates a swirling motion as the fluid flows over it. This turbulence is a more controlled form of turbulence that effectively mixes the fluid layers without causing significant splash or chaotic disturbances. This increases the heat exchange surface area as well as educates the fluid conducting an interaction between the fluid layers, enhancing the cooling effectiveness.

By inducing controlled turbulence, the circular weir design promotes more uniform heat transfer throughout the entire volume of the tank. This is because the swirling motion helps in distributing the cooler temperatures more evenly across all levels of the fluid, rather than just at the surface.

The circular weir design potentially reduces the energy required to maintain the flow. The natural momentum of the swirling fluid reduces the need for high-powered pumps to maintain circulation, and the efficient mixing reduces temperature stratification, which can otherwise require additional energy inputs to manage.

In some examples, the weir is made from corrosion-resistant materials like high-grade steel, stainless steel or aluminum. This ensures durability and also supports optimal thermal conductivity. The circular weir is precisely engineered for exact control over the flow characteristics, making it adaptable to various industrial applications requiring specific cooling rates and patterns.

The weir described herein provides an induced turbulence that is a controlled form of turbulence applied with an internal 3 inch Vortex that, unlike uncontrolled turbulence, is used to enhance the mixing of fluid. This mixing promotes heat exchange between the fluid layers.

The weir provides enhanced cooling via heat release. As the returning flow hits the round weir, the induced turbulence facilitates a faster release of heat from the fluid. This is because the turbulent flow increases the surface area of the fluid in contact with cooler areas, thereby enhancing the overall cooling effect.

The weir provides an additive cooling effect. The combination of the manifold's even laminar flow and the weir's induced turbulence creates an additive cooling effect. The fluid is cooled first by the laminar flow across the tank, and further cooled by the enhanced heat release due to the turbulence. This ensures the fluid remains at an optimal temperature throughout the process.

The immersion tank described herein provides a ΔT (Delta T) of 35 to 40 degrees Fahrenheit. This performance stems from the system's design, functionality, and cooling capacity. The immersion tank has four times the cooling effect compared to traditional immersion tanks. This ΔT indicates the difference between the initial temperature of the fluid entering the tank and the temperature after it has been cooled and is exiting the system. A ΔT of 35 to 40 degrees is substantial and underscores several aspects of the immersion tank design described herein, especially when compared to standard industrial cooling technologies.

There are several implications of this temperate differential. A ΔT of 35 to 40 degrees demonstrates a high level of efficiency in heat transfer from the process or equipment being cooled to the cooling medium (typically water or another fluid). This indicates that our immersion tank efficiently absorbs heat from the ASIC placed inside it, rapidly lowering their temperature by a significant margin.

Achieving such a significant temperature drop typically requires an optimized flow of the cooling medium, which is facilitated by the design of the manifold and the circular weir. The manifold's configuration ensures an even laminar flow, which maximizes heat exchange surface contact with minimal turbulence. Simultaneously, the circular weir enhances the cooling effectiveness by promoting turbulence. The turbulence is a controlled turbulence that helps distribute the cooling effect uniformly throughout the tank.

The materials used in constructing the tank, manifold, and weir exhibits excellent thermal conductivity to facilitate this level of heat transfer. Additionally, these components need to maintain structural integrity at varying temperatures, ensuring that the ΔT does not lead to thermal stress or deformation.

Maintaining a ΔT of 35 to 40 degrees in a controlled manner also suggests that the system operates with considerable energy efficiency. The design likely minimizes the need for excessive power consumption, as effective heat transfer is achieved without the need for high-power pumps or extensive mechanical inputs.

This temperature differential indicates that the system can handle significant thermal loads, making it suitable for various industrial applications. The ability to achieve such a ΔT makes our system versatile and scalable across different settings and requirements.

The immersion tank described herein provides an innovative design that combines a uniquely configured manifold with a specially designed weir to enhance the Delta T performance and Laminar Flow. The manifold's offset holes promote an even, turbulence-free laminar flow, for consistent cooling, while the round weir introduces beneficial turbulence that further enhances the cooling by facilitating heat release. This synergistic design ensures efficient and effective temperature management in the immersion tank, setting it apart from other tanks with more traditional designs. This setup is particularly advantageous in industries where precise temperature control is crucial for the quality and stability of the product or process.

As utilized herein, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Further, as used herein, the term “exemplary” is intended to mean “serving as an illustration or example of something.”

Illustrative embodiments have been described, hereinabove. It will be apparent to those skilled in the art that the above devices and methods may incorporate changes and modifications without departing from the general scope of the claimed subject matter. It is intended to include all such modifications and alterations within the scope of the claimed subject matter. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An immersion tank, comprising:
an inlet to receive a fluid;
a manifold coupled to the inlet, the manifold having a plurality of chambers, wherein each chamber include a plurality of holes for emitting the fluid into an interior of the tank;
a weir, wherein the weir includes a weir opening to receive a fluid from the interior of the tank into a weir cavity, the weir cavity includes a vortex generator coupled to an outlet of the weir cavity; and
an outlet coupled to the outlet of the weir cavity.

2. The immersion tank of claim 1, further comprising a housing having a plurality of sidewalls to define an interior space.

3. The immersion tank of claim 2, further comprising a mesh inserted into the interior space providing a surface to support objects placed within the immersion tank.

4. The immersion tank of claim 3, wherein the manifold is positioned beneath the mesh in the interior space.

5. The immersion tank of claim 1, wherein the fluid is a dielectric fluid.

6. The immersion tank of claim 1, further comprising a drip tray positioned at an upper portion of the interior space.

7. The immersion tank of claim 1, wherein the vortex generator is formed by intersecting plates.

8. The immersion tank of claim 1, wherein a dimension of the vortex generator is greater than a dimension of the outlet of the weir cavity.

9. The immersion tank of claim 1, wherein the vortex generator is positioned above the outlet of the weir cavity.

10. The immersion tank of claim 1, wherein the vortex generator creates a swirling motion in the fluid as the fluid flows passed.

11. The immersion tank of claim 1, wherein the manifold is positioned at a bottom of the immersion tank.

12. The immersion tank of claim 1, wherein the manifold includes a plurality of channels extending along an interior perimeter of the immersion tank and along a central longitude of the interior.

13. The immersion tank of claim 1, wherein the manifold includes first and second transverse conduits, and wherein the second transverse conduit are longitudinally spaced from the first transverse conduit by a plurality of longitudinal conduits.

14. The immersion tank of claim 13, wherein the plurality of longitudinal conduits includes a first longitudinal conduit, a second longitudinal conduit, and a central longitudinal conduit positioned between the first and second longitudinal conduits, wherein the central longitudinal conduit extends between and along a line that bisects the first and second transverse conduits.

15. The immersion tank of claim 14, wherein the first transverse conduit includes an inlet in fluid communication with the inlet of the immersion tank, wherein the first transverse conduit is in fluid communication with the first and second longitudinal conduits, and wherein the central longitudinal conduit is closed at an end that abuts the first transverse conduit.

16. The immersion tank of claim 14, wherein the plurality of holes are positioned along the first, second, and central longitudinal conduits.

17. The immersion tank of claim 16, wherein the plurality of holes are on inner sides of the first and second longitudinal conduits and on both sides of the central longitudinal conduits.

18. The immersion tank of claim 16, wherein holes along one longitudinal conduit are offset relative to holes on an adjacent longitudinal conduit, and wherein adjacent holes along a side of a longitudinal conduit are separated by a first distance.

19. The immersion tank of claim 17, wherein holes along one side of the central longitudinal conduit are offset relative to holes along the other side of the central longitudinal conduit.

20. The immersion tank of claim 18, wherein the first distance is approximately between 1 inch to 2 inches, inclusive, and the offset is approximately between 0.25 inches to 1 inch, inclusive.
